(19) United States
(12) Patent Application Publication
(10) Pub. No.: US 2009/0212279 A1
(43) Pub. Date: Aug. 27, 2009

(54) Nanostructure-Based Electronic Device

(76) Inventors: Maozi Liu, Fremont, CA (US); Thomas E. Kopley, La Honda, CA (US); S. Jeffrey Rosner, Palo Alto, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 12/038,688

(22) Filed: Feb. 27, 2008

(51) Int. Cl. H01L 21/283; H01L 29/12

(52) U.S. Cl. 257/30; 438/674; 257/E29.069; 257/E21.159

(57) ABSTRACT

The nanostructure-based electronic device comprises a solid support, an organic template layer, a nanostructure and electrodes. The organic template layer is on the surface of the solid support, and has a surface comprising a pair of spaced, electrically-charged regions arranged in tandem in an electrically-neutral background. The nanostructure is elongate, is electrically-conducting, and extends between the charged regions. The electrodes are located the surface of the template layer and are at least co-extensive with the charged regions.

### BACKGROUND

Two basic approaches are used to manufacture nanostructure-based electronic devices. A top-down method, which is similar to that used for making integrated circuits, transfers patterns to a substrate using photolithography, and additionally involves material deposition and etching. A bottom-up method fabricates nanostructures, ideally molecule-by-molecule, or even atom-by-atom. Many advanced techniques have been developed to make many kinds of nanostructures, including single or multiple nanoparticles, nanotubes, nanowires, nanoribbons, etc. of various materials.

Carbon nanotubes (CNTs) have attracted much attention recently due to their impressive mechanical, electrical and optical properties. Extensive studies have been conducted on CNTs, especially on CNT-based field-effect-transistors (CNT FETs). However the difficulty of precisely locating the CNTs on a substrate and of making electrical connections to the CNTs is still a substantial obstacle to large-scale integration of CNT FETs.

In 73 APPL. PHYS. LETT., 2447-2449 (1998), R. T. Schmid et al. describe a top-down method for fabricating CNT FETs in which the CNTs are deposited from a dispersion in a liquid onto a substrate having predefined electrodes. The formation of a CNTFET with this approach relies on a CNT fortuitously coming to rest at location that bridges two of the pre-defined electrodes, and is therefore a random event. This process provides no control over the position of the CNTs, and integration is therefore impossible.

In 2 NANO LETTERS, 929-932 (2002), Ali Javey et al. describe a more refined top-down method for fabricating CNT FETs that uses catalyst-based chemical vapor deposition (CVD) to grow CNTs directly on the substrate. By using electron-beam lithography or photolithography to define the positions of the catalyst and electrodes, a non-negligible yield of operational CNT FETs can be obtained. However, this process is complicated and, in practice, is still somewhat random because it does not effectively control the orientation of the CNTs grown from the catalyst. In addition, the CVD growth method does not control the chirality (handedness) of the CNTs grown using this process. This means that the CNTs constituting the CNT FETs fabricated using this process have various bandgaps and include metallic CNTs that act as electrical short circuits.

In 302 SCIENCE, 1380-1382 (2003), Kinneret Keren et al. describe a more bottom-up method of fabricating CNT FETs using DNA templating, which is based on biological molecule recognition. In this method, a CNT functionalized with streptavidin is bound to double-stranded DNA (dsDNA) that has been functionalized with biotin. Once the CNT is located on the dsDNA, the DNA is metallized with silver and gold using a known process. This forms electrodes that are self-aligned with the CNT. While this method is elegant, to use in a practical application, it requires that the dsDNA be located on the substrate with an accuracy that is difficult to achieve in practice.

In 103 PNAS 2028-2031 (2006), Yuhuang Wang et al. describe another bottom-up approach in which dip pen nanolithography is used to deposit patterns of a carboxyl (COOH)-terminated self-assembled monolayer (SAM) on a gold surface. The remaining exposed gold surface is passivated with a CH₃-terminated SAM, and the surface is exposed to a suspension of CNTs. The CNTs preferentially align with the COOH-SAM patterns. This allows precise placement of CNTs on the surface, but the gold surface does not allow bottom-gate CNT FETs to be formed. Nor does the gold surface easily allow multiple aligned mask layers to be used to fabricate more complicated gate CNTFET structures.

U.S. patent application Ser. No. 11/488,386, assigned to the assignee of this application and incorporated by reference, discloses a method of fabricating a device comprising an elongate nanostructure immobilized by a charged feature in a defined region of the surface of a solid support. In the method, the surface of the solid support comprising the charged feature region is contacted with a fluid composition of elongate nanostructures having an affinity for the charged feature region. The affinity between the elongate nanostructure and the charged feature region causes the elongate nanostructure to position preferentially in alignment with the charged feature region. Nanostructures on the surface not aligned with the charged feature regions are separated from the surface to produce the device. FIG. 5 of the disclosure shows an example of a single-wall carbon nanotube immobilized on the surface of a substrate spanning two elongate charged feature regions defined on the surface. The process precisely defines the locations of CNTs on the surface of a substrate, but does not provide electrodes that make electrical contact with the ends of the CNTs so that the CNTs may constitute parts of respective electronic devices, such as CNT FETs.

Accordingly, what is needed is a way to make electrical contact with the ends of a CNT located on the surface of the substrate to allow the CNTs to constitute part of an electronic device, such as a CNTFET.

### BRIEF DESCRIPTION OF THE DRAWINGS

FIG. 1A is a plan view showing an example of an electronic device in accordance with an embodiment of the invention.

FIG. 1B is a cross-sectional view along section line 1B-1B in FIG. 1A.

FIG. 1C is an enlarged view of region IC shown in FIG. 1B.

FIG. 2 is a flow chart showing an example of a method in accordance with an embodiment of the invention for fabricating a nanostructure-based electronic device.

FIGS. 3A, 4A, 5A, 6A, 7A, 8A, 9A, 10A, 11A and 12A are plan views illustrating an example of a fabrication method that can be used to fabricate an embodiment of a nanostructure-based electronic device such as that shown in FIGS. 1A-1C.

FIGS. 3B, 4B, 5B, 6B, 7B, 8B, 9B, 10B, 11B and 12B are cross-sectional views along section lines 3B-3B, 4B-4B, 5B-5B, 6B-6B, 7B-7B, 8B-8B, 9B-9B, 10B-10B, 11B-11B and 12B-12B, respectively, in FIGS. 3A, 4A, 5A, 6A, 7A, 8A, 9A, 10A, 11A and 12A, respectively.

FIGS. 8C, 9C, 10C, 11C and 12C are enlarged views of regions 8C, 9C, 10C, 11C and 12C, respectively, shown in FIGS. 8B, 9B, 10B, 11B and 12B, respectively.

FIG. 13A is a plan view showing an example of an electronic device in accordance with another embodiment of the invention.

FIG. 13B is a cross-sectional view along section line 13B-13B in FIG. 13A.

FIG. 14 is a plan view showing an example of an electronic device in accordance with another embodiment of the invention.

FIG. 15A is a plan view showing an example of an electronic device in accordance with yet another embodiment of the invention.

FIG. 15B is a cross-sectional view along section line 15B-15B in FIG. 15A.

### DETAILED DESCRIPTION

Embodiments of the invention provide a nanostructure-based electronic device, such as a carbon nanotube field-effect transistor (CNTFET), that comprises a solid support having a support surface, and an organic template layer on the support surface. The template layer has a surface comprising a pair of spaced, electrically-charged regions arranged in tandem in an electrically-neutral background. The electronic device additionally comprises an elongate, electrically-conducting nanostructure extending between the charged regions, and electrodes on the surface of the template layer at least co-extensive with the charged regions and in electrical contact with the nanostructure.

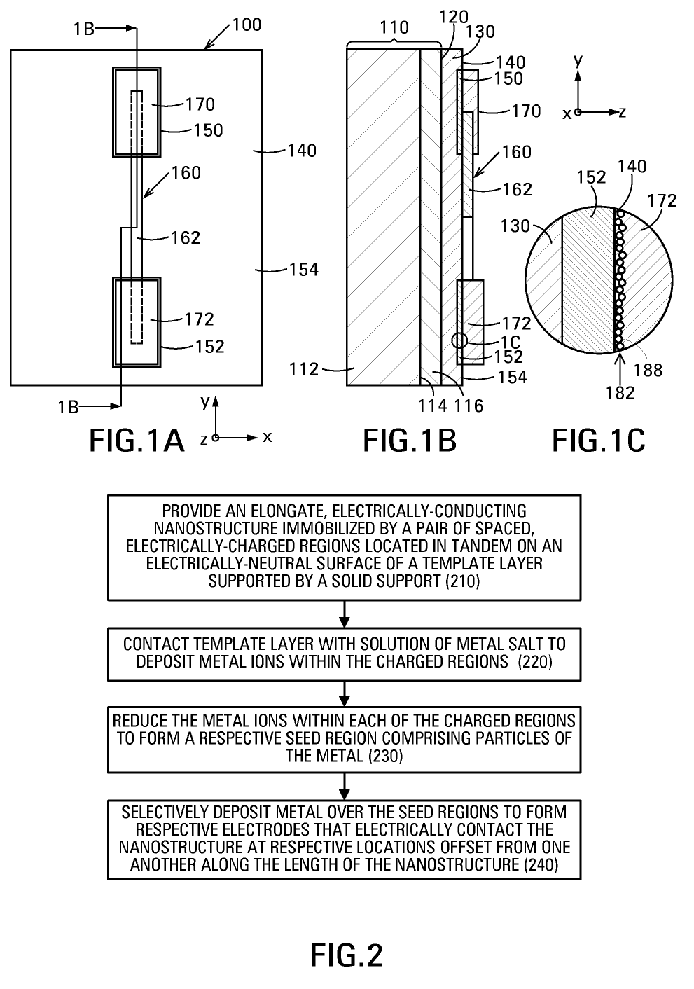

FIGS. 1A and 1B are respectively a plan view and a cross-sectional view showing an example of a nanostructure-based electronic device 100 in accordance with an embodiment of the invention. Electronic device 100 is composed of a solid support 110 having a support surface 120. An organic template layer 130 is located on support surface 120. Template layer 130 has a surface 140 that comprises electrically-charged regions 150, 152 in an electrically-neutral background 154. Electrically-charged regions 150, 152 are arranged in tandem and are spatially offset from one another. An elongate nanostructure 160 extends between charged regions 150, 152. Electrodes 170, 172 are located on the surface of template layer 130 and are at least co-extensive with charged regions 150, 152, respectively. Additionally, electrodes 170, 172 make electrical contact with nanostructure 160 at regions spatially offset from one another along the length of the nanostructure.

FIG. 1A shows charged regions 150, 152 as extending laterally beyond electrodes 170, 172, respectively, on surface 140. This is simply a drafting artifact to enable the charged regions to be seen in the plan view. In practice, electrodes 170, 172 are at least co-extensive with charged regions 150, 152, respectively, as noted above. Alternatively, electrodes 170, 172 may extend beyond charged regions 150, 152.

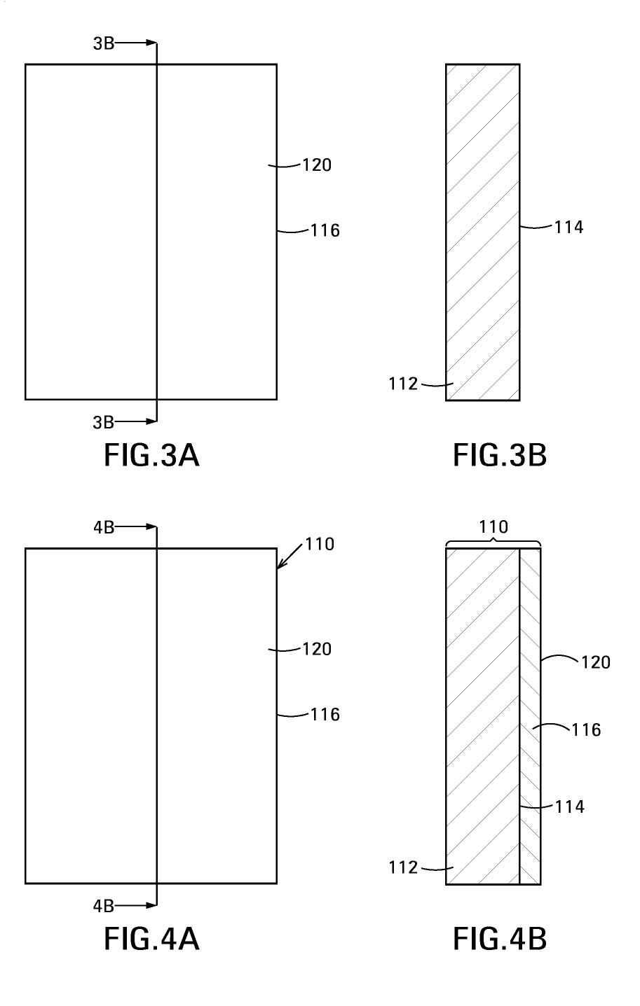

During fabrication of electronic device 100, the charged regions 150, 152 in the surface 140 of template layer 130 immobilize nanostructure 160 on surface 140 with the nanostructure extending between the charged regions. Then, in a subsequent operation in which electrodes 170, 172 are formed, charged regions 150, 152 define the locations of electrodes 170, 172. Since the location of nanostructure 160 and the locations of electrodes 170, 172 on surface 140 are all defined by the same features, namely, charged regions 150, 152, electrodes 170, 172 are located so that they automatically make electrical contact with nanostructure 160. A process for fabricating electronic device 100 will be described below with reference to FIG. 2 and, in more detail, with reference to FIGS. 3A-12C.

In some embodiments, electronic device 100 is a type of field-effect transistor having nanostructure 160 as its channel, and electrodes 170, 172 as its source and drain electrodes, respectively. In some embodiments, current flow between source and drain is controlled by applying a voltage to a nearby gate electrode (not shown). In one example, the gate electrode is located on the surface of solid support 110 beneath nanostructure 160. In another example, the gate electrode is located over the nanostructure. In either case, the techniques described herein for defining the location of electrodes 170, 172 on surface 140 can be used to define the location of the gate electrode. For example, in the gate-over example, after electrodes 170, 172 have been formed, an additional insulating layer (not shown) is deposited over template layer 130 and nanostructure 160, an additional template layer (not shown) is deposited on the additional insulating layer, an additional charged region (not shown) is defined in the surface of the additional template layer at the design location of the gate electrode, an additional seed layer is deposited in the additional charged region, and the gate electrode (not shown) is formed over the additional seed layer, i.e., in the additional charged region.

In another example, current flow between source and drain is controlled by locating electrically-charged molecules proximate to the nanostructure. In this example, the nanostructure is functionalized with molecules capable of binding to other molecules that will be referred to as target molecules. When exposed to a fluid containing the target molecules, the target molecules bind to the functionalizing molecules and charge carried by the target molecules changes the conductivity of the nanostructure that provides the channel of the field-effect transistor. The conductivity of the nanostructure is measured by passing a current through the channel from electrode 170 to electrode 172 and measuring the voltage between electrode 170 and electrode 172. Alternatively, a current that flows through the nanostructure in response to a voltage applied between electrodes 170 and 172 can be measured. Techniques for functionalizing nanostructures with molecules capable of binding to other molecules are known in the art and can be used.

In embodiments in which the electronic device is a field-effect transistor, nanostructure 160 is a semiconductor nanostructure, such as a Group IV semiconductor nanostructure such as a carbon nanostructure, a silicon nanostructure, or a germanium nanostructure; a Group III-V semiconductor nanostructure such as a gallium arsenide nanostructure; or a Group II-VI semiconductor nanostructure such as a cadmium sulfide nanostructure semiconductor. Semiconductor nanostructures are regarded as being electrically conducting for the purpose of this disclosure. The semiconductor materials are doped with suitable dopants to define their electrical conduction properties. Dopants suitable for doping the semiconductor materials mentioned above are known in the art and may be used.

In other embodiments, nanostructure 160 provides a low-resistance electrical connection between electrodes 150, 152. In such embodiments, nanostructure 160 is a metallic nanostructure such as a metallic carbon nanotube or a metallic nanowire. Metallic nanowires can be made of such metals as silver, gold or any other metal that can form nanowires.

In the example of electronic device 100 shown in FIG. 1A, solid support 110 is composed of a substrate 112 having a substrate surface 114. Located on substrate surface 114 is an insulating layer 116 whose surface provides support surface 120. Typically, the material of substrate 112 is single-crystal silicon. Other suitable substrate materials include glass, sapphire and other single-crystal semiconductors such as germanium and gallium arsenide. Typically, the material of insulating layer 116 is silicon dioxide SiO₂. Alternative materials for insulating layer 116 include silicon nitride Si₃N₄ and aluminum oxide Al₂O₃. Insulating layer 116 is typically deposited on the substrate surface 114 by a suitable deposition process, such as metal-organic chemical vapor deposition (MOCVD). Alternatively, insulating layer 116 can be a layer of native oxide in embodiments in which the material of substrate 112 is silicon.

In the example of electronic device shown in FIG. 1A, template layer 130 is a thin film, e.g., a self-assembled monolayer (SAM). The thin film exhibits desired terminal groups, e.g., charge-neutral terminal groups, that can be selectively converted into terminal groups that exhibit a desired charge, e.g., positive or negative. For example, a neutral terminal group can be converted into a charged terminal group such as a carboxyl group, a thiol group, a disulfide group, an amino group, a phosphate group, or another charged terminal group. Such conversion amounts to oxidation of the surface of the template layer. Of interest are molecules that can be caused to undergo the desired conversion by subjecting them to, e.g., an electrical field, a localized chemical reaction or charge injection, etc. For example, one suitable type of self-assembling molecule is one that has a terminal methyl group CH₃ that application of an electric field converts, via oxidation, into a terminal carboxyl group COOH.

In certain embodiments, the self-assembling molecules are silane molecules. Of interest are silane molecules of the formula CH₃— (CH₂)ₙ—SiR₃, where n=an integer from 1 to about 30; and R is a halogen, such as chloro; a hydroxyl; or a lower (C₁-C₆) alkoxy, such as methoxy. In certain embodiments, the silane molecule is n-octadecyl-trimethoxyl-silane having the formula: CH₃—(CH₂)₁₇—Si(OCH₃)₃. Other self-assembling molecules of interest include, but are not limited to, unsaturated alkyl silanes; organothiol molecules that form a self-assembled monolayer on a surface of a noble metal such as gold; alkenes, alkynes, and alkyl alcohols that form a self-assembled monolayer on a silicon surface; molecules that form a Langmuir-Blodgett film on the surface of a solid support, etc. In some embodiments, the surface 140 of template layer 130 is composed of molecules of a single type such that it is a homogeneous layer with respect to its constituent SAMs. In other embodiments, the surface of template layer 130 is composed of molecules of two or more different types such that it is heterogeneous with respect to its constituent SAMs.

In the example of electronic device 100 shown in FIG. 1A, charged regions 150, 152 are elongate in the direction in which they are arranged in tandem.

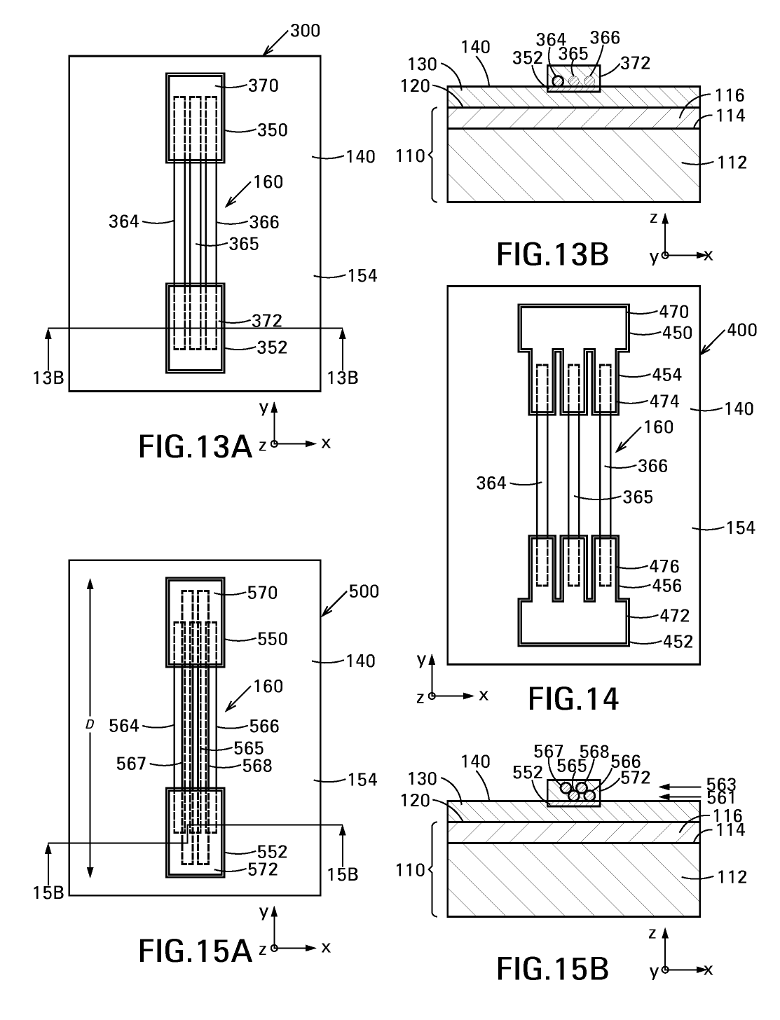

In electronic device 100, examples of elongate nanostructures that may be used as nanostructure 160 include a single elongate nanoelement such as a nanotube, a nanowire, a nanorod, a nanoribbon, or a nanofiber. In the example shown in FIGS. 1A and 1B, nanostructure 160 is composed of a single carbon nanotube 162. Additionally, as will be described in more detail below with reference to FIGS. 13A, 13B, 14A and 14B, nanostructure 160 may be composed of several elongate nanoelements arranged side-by-side.

FIG. 1C is an enlarged view showing part of template layer 130 in which charged region 152 is defined, and part of electrode 172. FIG. 1C additionally shows the structure of electrode 172 in more detail. Electrode 172 is located on a seed region 182. Seed region 182 is a thin layer of metal particles located on the surface 140 of template layer 130 within charged region 152. An exemplary one of the metal particles constituting seed region 182 is shown at 188. Electrode 172 is a layer of metal overlaying seed region 182 and is substantially greater in thickness than the seed region. The thickness of electrode 172 is sufficient to cover nanostructure 160 so that the electrode provides a low-resistance electrical connection to nanostructure 160 part-way along the length of nanostructure 160.

In the x-y plane parallel to the surface 140 of template layer 130, the location and lateral extent of seed region 182 are defined by the location and lateral extent of the charged region 152 of surface 140. The location and lateral extent of electrode 172 are in turn defined by the location and lateral extent of seed region 182. Thus, in the example shown, electrode 172 is substantially co-extensive with charged region 152. Although not shown in detail, the location and lateral extent of electrode 170 are defined by the location and lateral extent of a seed region (not shown) within charged region 150. The location and lateral extent of the seed region underlying electrode 170 are in turn defined by the location and lateral extent of charged region 150. Thus, in the example shown, electrode 170 is substantially co-extensive with charged region 150.

In one example, seed region 182 is composed of particles of silver Ag. In other examples, seed region 182 is composed of particles of gold Au or palladium Pd. The metal of electrode 172 is the same as that of seed region 182. Alternatively, the metal of electrode 172 is different from that of the seed region 182. In another alternative, electrode 172 is composed of layers of different metals. In one example, electrode 172 is composed of layers of copper Cu. Typically, the metal layer of electrode 172 in contact with seed region 182 is a layer of the same metal as seed region 182.

Solid support 110 may be non-conducting, semiconducting, conducting, or highly conducting. In examples of a semiconducting solid support, the solid support is all or part of a wafer of a semiconductor such as silicon, germanium, gallium arsenide, gallium nitride, indium phosphide or another Group IV, Group III-V, Group II-VI semiconductor. In examples of a highly-conducting solid support, the material of the solid support is a metal such as gold, silver, copper, palladium, aluminum, etc.

Suitable solid supports can have a variety of forms and compositions and can be derived from naturally-occurring materials, naturally-occurring materials that have been synthetically modified, or synthetic materials. Examples of suitable materials for the solid support include, but are not limited to, nitrocellulose, glasses, ceramics and metals. Suitable materials also include polymeric materials, including plastics (for example, polytetrafluoroethylene, polypropylene, polystyrene, polycarbonate, and blends thereof, and the like), polysaccharides such as agarose and dextran, polyacrylamides, polystyrenes, polyvinyl alcohols, copolymers of hydroxyethyl methacrylate and methyl methacrylate, and the like. The solid support may be homogenous or a composite structure of two or more different materials, e.g., where the solid support includes a first base material that is coated on a surface with one or more additional different coating materials. For example, the solid support may be a composite that is made of a base layer of glass coated with a surface layer of a metal such as gold.

Solid support 110 may have any desired configuration. In certain embodiments, the solid support is in the form of a substrate and/or wafer that includes a planar surface on which one or more nanostructure-based electronic devices will be fabricated. The solid support may be a uniform solid support, e.g., a wafer of solid material, such as silicon, glass, quartz, ceramic, plastic, etc.; a large rigid sheet of a solid material such as glass, quartz, ceramic, a plastic such as polycarbonate, polystyrene, etc., or can comprise additional elements, e.g., structural, compositional, etc. elements. A flexible solid support, such as a roll of a plastic material such as a polyolefin, polyamide, and others, a transparent solid support, or combinations of these features can be employed. For example, the solid support may include other circuit or structural elements that are part of the ultimately desired device. Particular examples of such elements include electrical circuit elements such as electrical contacts, other wires or electrically-conductive paths, including nanowires or other nanoscale electrically-conducting elements, optical and/or optoelectronic elements (e.g., lasers, LEDs, etc.), semiconductor devices such as transistors and integrated circuits, and structural elements (e.g., microcantilevers, pits, wells, posts, etc.).

Nanostructure 160 may be any nanostructure of suitable dimensions and having an affinity with charged regions 150, 152. In certain embodiments, nanostructure 160 is a charged nanostructure. A charged nanostructure is a composition of matter (e.g., of a single element or made up of two or more elements (which may be the same or different)) that is of nanometer dimensions and has an overall net charge of a polarity opposite that of charged regions 150, 152. In other embodiments, nanostructure 160 is uncharged and yet has an affinity with charged regions 150, 152. Nanostructure 160 may be functionalized by means other than electrical charge to increase its affinity with charged regions 150, 152. The nanostructure has an elongate shape such that of a rod, a tube, a wire, a ribbon, a rope, etc. The nanostructure has dimensions, e.g., length, width, height, ranging from about 1 nm to about 100 μm, such as from about 2 nm to about 100 nm.

Nanostructure 160 is typically composed of one or more elongate nanoelements, such as a nanowire, a nanorod, a nanoribbon, a nanotube, a nanorope or another suitable elongate nanoscale structure. As used herein, the term nanowire refers to any elongate structure of an electrically-conducting material that has at least one cross sectional dimension less than 500 nm, such as less than 100 nm, and has an aspect ratio (length:width ratio) of greater than 10, such as greater than 50, and including greater than 100. Examples of such nanowires include semiconductor nanowires as described in published international patent application nos. WO 02/17362, WO 02/48701, and WO 01/03208, each of which is incorporated by reference. Other examples include carbon nanotubes and other elongate structures of conducting or semiconducting materials of like dimensions.

Nanowires of interest include nanowires of such materials as Si, Ge, Sn, Se, Te, B, C (including diamond), B—C, B—P(BP₆), B—Si, Si—C, Si—Ge, Si—Sn and Ge—Sn, SiC, BN/BP/BAs, AlN/AlP/AlAs/AlSb, GaN/GaP/GaAs/GaSb, InN/InP/InAs/InSb, BN/BP/BAs, AlN/AlP/AlAs/AlSb, GaN/GaP/GaAs/GaSb, InN/InP/InAs/InSb, ZnO/ZnS/ZnSe/ZnTe, CdS/CdSe/CdTe, HgS/HgSe/HgTe, BeS/BeSe/BeTe/MgS/MgSe, GeS, GeSe, GeTe, SnS, SnSe, SnTe, PbO, PbS, PbSe, PbTe, CuF, CuCl, CuBr, CuI, AgF, AgCl, AgBr, AgI, BeSiN₂, CaCN₂, ZnGeP₂, CdSnAs₂, ZnSnSb₂, CuGeP₃, CuSi₂P₃, (Cu,Ag)(Al,Ga,In,Tl,Fe)(S,Se,Te)₂, Si₃N₄, Ge₃N₄, Al₂O₃, (Al,Ga,In)₂ (S,Se,Te)₃, Al₂CO, and other appropriate combinations of two or more such materials.

In certain aspects, the nanowire material is a semiconductor material and comprises a dopant such as a p-type dopant from Group III of the periodic table, such as B, Al and In; an n-type dopant from Group V of the periodic table, such as P, As and Sb; a p-type dopant from Group II of the periodic table, such as Mg, Zn, Cd and Hg; a p-type dopant from Group IV of the periodic table, such as C and Si; or an n-type dopant from Group IV of the periodic table, such as Si, Ge. Other dopants include Sn, S, Se and Te.

Nanowires with more complex structures than the homogeneous nanowires just described are also known. The structures can be more complex radially, axially, or both. For example, nanowire superlattices composed of materials that alternate in the axial direction of the nanowire (e.g., Ag/Au “nanobarcodes”) are known. “Core-shell” nanowires are also known in which the nanowire has a core of one material and a shell of another material (e.g., a GaAs core and a AlGaAs shell).

Elongate nanostructures of interest, e.g., elongate nanostructures composed of single or multiple elongate nanoelements such as nanotubes, nanowires, nanorods, nanoribbons, nanoropes, etc., include, but are not limited to, those reviewed by Law et al. in Semiconductor Nanowires and Nanotubes, 34 ANNU. REV. MATER. RES., 83-122 (2004).

FIG. 2 is a flow chart showing an example of a method 200 in accordance with an embodiment of the invention for fabricating a nanostructure-based electronic device.

In block 210 an elongate, electrically-conducting nanostructure is provided. The nanostructure is immobilized by a pair of spaced, electrically-charged regions located in tandem on an electrically-neutral surface of a template layer supported by a solid support.

In block 220, the template layer is contacted with a solution of a metal salt to deposit metal ions within the charged regions.

In block 230, the metal ions within each of the charged regions are reduced to form a respective seed region comprising particles of the metal.

In block 240, metal is selectively deposited over the seed regions to form respective electrodes that electrically contact the nanostructure at respective locations offset from one another along the length of the nanostructure.

The method described above with reference to FIG. 2 will now be described in further detail. In block 210, the location at which the nanostructure is immobilized on the surface of the template layer is defined by the locations of the charged regions in the surface. The nanostructure is either electrically neutral, or carries an electric charge opposite that of the charged regions. Electrostatic attraction or van der Waals interaction between the nanostructure and the charged regions immobilizes the nanostructure on the surface of the template layer in a location defined by the locations of the charged regions in the surface of the template layer.

In block 220, the charged regions in the surface of the template layer carry a negative electric charge. A solution of a metal salt contains metal ions, which carry a positive electric charge. When the template layer is contacted with the metal salt solution, the metal ions are attracted towards the charged regions in the surface of the template layer, where they accumulate.

In block 230, the metal ions accumulated in the charged regions in the surface of the template layer are reduced to form respective seed regions composed of particles of the metal. While such seed regions can be described as electrically-conducting, the seed regions would not function well as electrodes because they have a relatively low electrical conductivity and such electrical contacts as they form with the nanostructure are high in electrical resistance.

In block 240, the metal selectively deposited over the seed region in each of the charged regions forms an electrode having a high electrical conductivity and that makes a low-resistance contact with the nanostructure. In an example, the metal is selectively deposited by electroless plating. In an example in which an electrical connection can be conveniently made to the seed regions, the metal is selectively deposited by conventional electro-plating. In another example in which an electrical connection can be conveniently made to the seed regions, a thin layer of the metal is initially selectively deposited by electroless plating and the remainder of the metal is selectively deposited by conventional electro-plating.

Wafer-scale fabrication is used to fabricate thousands of nanostructure-based electronic devices similar to above-described nanostructure-based electronic device 100 at the same time. Such wafer-scale fabrication makes the nanostructure-based electronic devices inexpensive to fabricate. An example of a fabrication method that can be used to fabricate an embodiment of nanostructure-based electronic device 100 described above with reference to FIGS. 1A-1C will be described next with reference FIGS. 3A, 3B, 4A, 4B, 5A, 5B, 6A, 6B, 7A, 7B, 8A-8C, 9A-9C, 10A-10C, 11A-11C and 12A-12C (FIGS. 3A-12C).

The nanostructure-based electronic devices are fabricated on a wafer having a planar surface. A portion of the wafer constitutes, for each nanostructure-based electronic device being fabricated, a substrate corresponding to the substrate 112 of nanostructure-based electronic device 100. FIGS. 3A-12C illustrate and the following description describes the fabrication of nanostructure-based electronic device 100 on a portion of the wafer that constitutes substrate 112. As nanostructure-based electronic device 100 is fabricated, the remaining nanostructure-based electronic devices on the wafer are similarly fabricated. References below to the wafer are references to the wafer of which substrate 112 constitutes part.

A substrate is provided. FIGS. 3A and 3B show an example of substrate 112. Substrate 112 has a substrate surface 114. In the example shown, the wafer of which substrate 112 constitutes part is a wafer of single-crystal silicon, and the material of substrate 112 is therefore single-crystal silicon.

FIGS. 4A and 4B show solid support 110 composed of insulating layer 116 located on the surface 114 of substrate 112. Insulating layer 116 may be obtained by converting part of substrate 112 adjacent surface 114 to an insulting material. For example, in an embodiment in which the material of substrate 112 is single-crystal silicon, the substrate is heated to a temperature in the range 900° C.-1200° C. in an ambient of oxygen and, optionally, steam to convert part of the silicon substrate adjacent surface 114 to native silicon dioxide SiO₂ that provides insulating layer 116. In another example, insulating layer 116 is formed by depositing a layer of silicon dioxide on the surface 114 of substrate 112. Suitable deposition processes include chemical vapor deposition (CVD) and plasma-enhanced CVD (PECVD). Suitable precursors for silicon dioxide include silane (SH₄) or tetra-ethyl-ortho-silicate (TEOS) and oxygen or ozone. Another suitable material for insulating layer 116 is silicon nitride (Si₃N₄). Many other materials that provide electrical insulation, that will adhere to substrate 112 and template layer 130 (FIG. 1), that are compatible with subsequent processing, and that are therefore suitable for use as insulating layer 114 are known in the art and may be used. Precursor materials and processes for depositing such materials are also known in the art and may be used.

In an embodiment in which substrate 112 is single-crystal silicon, insulating layer 116 is a layer of native oxide grown on substrate 112. In embodiments in which the material of substrate 112 is insulating and is a material to which the material of template layer 130 will adhere, insulating layer 116 may be omitted.

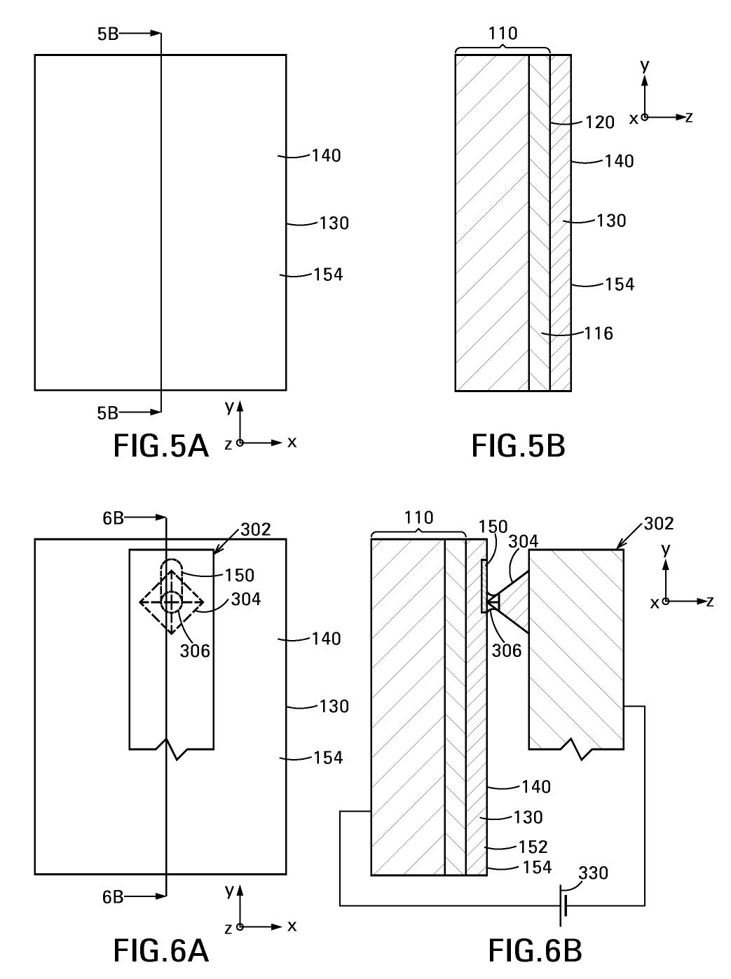

A template layer is deposited on the surface of the substrate. FIGS. 5A and 5B show template layer 130 located on the surface 120 of solid support 110. Template layer 130 is a layer of a material that, when deposited on insulating layer 114, forms an electrically-neutral surface 140 in which electrically-charged regions can be defined. In an example, template layer 130 is deposited by immersing the wafer in a 5 mM solution of n-octadecyltrimethoxylsilane in toluene for 2 minutes, followed by sonication in pure toluene for 2 minutes. This process is repeated three times. The wafer is then heated to 110° C. for 15 minutes to enhance the formation of the template layer. The resulting wafer is stored in a nitrogen dry box prior to use.

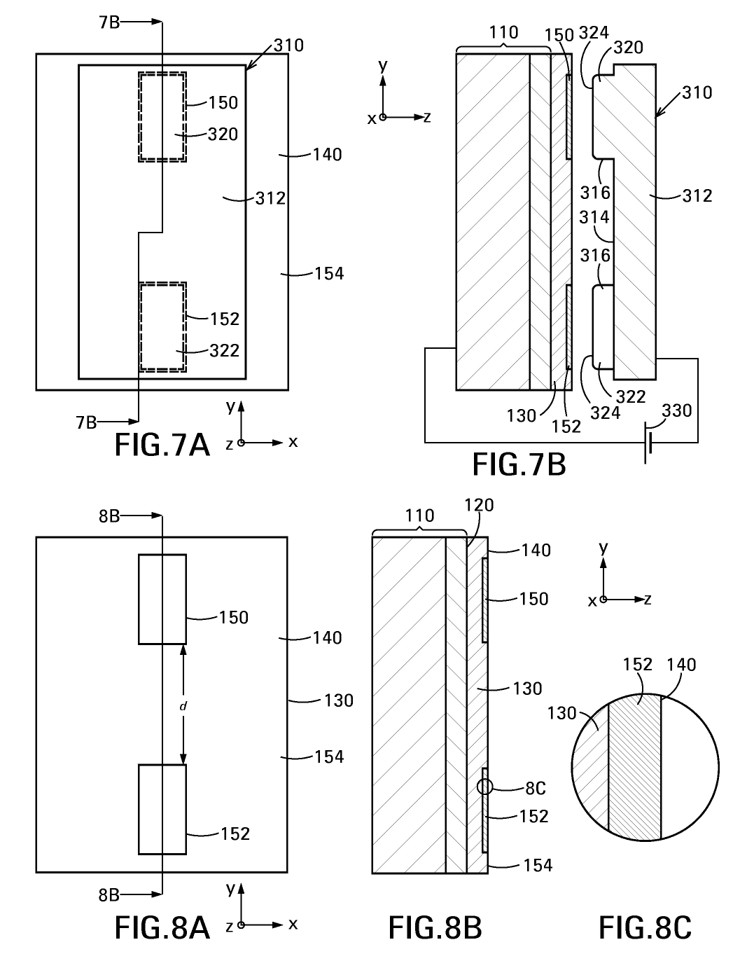

Electrically-charged regions are defined in the surface of the template layer. FIGS. 6A and 6B illustrate one exemplary process that can be used to define charged region 150 in the surface 140 of template layer 130. Charged region 152 is defined by repeating the process used to define charged region 150. Alternatively, charged regions 150, 152 may be defined by the same process, as will be described below with reference to FIGS. 7A and 7B.

Immediately prior to defining charged regions 150, 152 in the surface 140 of template layer 130, the wafer is sonicated in methanol for 1 minute and blown dry using dry nitrogen. The topology of the surface 140 of template layer 130 is then characterized by AFM imaging either in contact mode or noncontact imaging mode.

The AFM is then fitted with a conductive cantilever 302 having a conductive tip 304. Conductive tip 304 is directly or indirectly electrically connected to one terminal of a voltage source 330. The other terminal of the voltage source is connected to the wafer. The AFM is then operated to move conductive tip 304 in the −z-direction to bring the conductive tip into contact or close proximity with the surface 140. Voltage source 330 is activated to apply a negative voltage between the conductive tip and the wafer. The voltage is typically in the range from −5V to −8V. The voltage is chosen such that only the terminal methyl groups of the octadecyltrimethoxylsilane self assembled monolayer constituting template layer 130 in a circular region 306 of surface 140 surrounding conductive tip 304 are oxidized to carboxyl groups. The extent of the region 306 of surface 140 depends on the relative humidity of the ambient in which the oxidation process is performed. The extent increases with increased humidity. In embodiments in which the design length (dimension in the y-direction) of charged regions 150, 152 is greater than the length of region 306, the AFM is operated to move conductive tip 304 in the −y-direction while the voltage remains applied to the conductive tip. In embodiments in which the design width (dimension in the x-direction) of charged regions 150, 152 is greater than the width of region 306, the y-direction scan just described is repeated at least once. Prior to each repetition, AFM is operated to move conductive tip 304 in the x-direction by a distance less than the width of region 306.

Once conductive region 150 has been defined in surface 140, the AFM is operated to move conductive tip 304 in the x- and y-directions to the desired location of charged region 152. The process just described is then repeated to define charged region 152 in surface 140. In some embodiments, the process just described is repeated at least once to define respective additional pairs of charged regions similar to charged regions 150, 152 in surface 140. For example, the process just described is repeated to define in surface 140 at least one pair of charged regions similar to charged regions 150, 152 for each electronic device fabricated on the wafer. When many electronic devices are fabricated in the wafer, defining the charged regions individually can be quite time consuming.

FIGS. 7A and 7B illustrate another exemplary process that can be used to define charged regions 150, 152 in the surface 140 of template layer 130. Immediately prior to performing this process to define the charged regions in the surface of the template layer, the wafer is cleaned and dried as described above.

The process defines charged regions 150, 152, simultaneously in a single operation using an electrode tool 310. With embodiments of electrode tool 310 more complex than that shown, the process can be used to define simultaneously in a single operation more than two charged regions of a single electronic device, all of the charged regions of more than one electronic device, or all of the charged regions of all of the electronic devices fabricated on the wafer.

Electrode tool 310 is composed of a substrate 312 having a major surface 314. Electrode tool 310 is mounted on a stage (not shown) that disposes surface 314 parallel to the x-y plane. The stage is capable of moving the electrode tool in the x-, y- and z-directions. The stage also holds the wafer with the surface 140 of template layer 130 disposed parallel to the x-y plane and facing the major surface 314 of electrode tool 310.

Located on the surface 314 of the substrate 312 of electrode tool 310 is an electrode 316 corresponding to each charged region to be defined in the surface 140 of the template layer 130. Electrodes 316 corresponding to charged regions 150 and 152 are additionally labelled 320 and 322, respectively. Electrodes 320, 322 are positioned on surface 314 in locations corresponding to the desired relative locations of charged regions 150, 152. Each electrode 316 has a plane electrode surface 324 disposed parallel to the x-y plane. Each electrode surface 324 has a nominal extent equal to the design extent in the x-y plane of the corresponding charged region. For example, the electrode surfaces 324 of electrodes 320 and 322 have nominal extents equal to the design extents in the x-y plane of charged regions 150 and 152, respectively. In practice, the electrodes surfaces are slightly smaller in extent than the design extent of the charged regions.

In some embodiments, electrode tool 310, including substrate 312 and electrodes 316, is fabricated from a piece of electrically-conducting material such as a slab of metal. Alternatively, electrode tool 310 is fabricated from a piece of insulating material having an electrically-conducting layer (not shown) on one of its major surfaces, i.e., the major surface that faces template layer 130 when electrode tool 310 is mounted as described above. In such embodiments, the electrode tool is shaped such that electrodes 316 project in the −z-direction from the surface 314 of substrate 312, as shown in FIG. 7B. In other embodiments of electrode tool 310, the material of substrate 312 is electrically insulating, and only electrodes 316 are electrically conducting. In some of such embodiments, electrodes 316 project in the −z-direction from surface 314, as shown in FIG. 7B. In others of such embodiments, electrodes 316 are flush with surface 314. Typically, the corners of electrodes 316 facing away from substrate 312 are rounded to increase the uniformity of the electric field applied by the electrodes of electrode tool 310. In all embodiments, electrodes 316 are directly or indirectly electrically connected to one terminal of a voltage source 330. The other terminal of the voltage source is connected to the wafer

Electrode tool 310 is mounted in the stage (not shown) with surface 314 parallel to the surface 140 of template layer 130 and with electrode surfaces 324 separated from the surface 140 of template layer 130 in the +z-direction. The stage is operated to move electrode tool 310 in the x-y plane to align electrodes 320 and 322 with the design locations of charged regions 150, 152 on surface 140. For example, the stage may be operated to align electrode 320, 322 relative to a gate electrode (not shown) located on the surface 120 of the insulating layer 116 (FIG. 4B) that constitutes part of solid support 110. The stage is then operated to move electrode tool 310 in the −z-direction to bring electrode surfaces 324 into contact with the surface 140 of template layer 130. Alternatively, the stage may be operated to move the electrode tool in the −z-direction such that electrode surfaces 324 are separated from surface 140 by a small distance in the range from several nanometers to tens of nanometers.

Voltage source 330 is activated to apply a negative voltage between electrodes 316 and the wafer. The voltage is chosen to subject the region of template layer 130 underlying each of the electrodes 316 to an electric field intensity similar to that imposed by a negative voltage in the range from −5V to −8V applied to above-described conductive tip 304 The voltage will be greater in magnitude than those applied to conductive tip 304. The voltage is chosen such that only the terminal methyl groups of the octadecyltrimethoxylsilane self assembled monolayer constituting template layer 130 in contact with electrodes 316 are oxidized to carboxyl groups. The voltage applied to electrodes 316 oxidizes a region of surface 140 in contact or in proximity with each electrode and an additional, narrow region of surface 140 surrounding each electrode. Such additional region is analogous to region 306 shown in FIGS. 6A and 6B. The width of the additional region depends on the relative humidity of the ambient in which the oxidation process is performed. The width of the additional region increases with increased humidity. The time for which the voltage is applied is in the range from microseconds to minutes, with 2 seconds being typical. After application of the voltage to electrodes 316, the stage is operated once more to move electrode tool 310 in the +z-direction. This separates electrode tool 310 from the wafer so that the wafer can be removed from the stage. FIG. 7B shows the wafer and electrode tool after the voltage application and separation operations have been performed.

After charged regions 150, 152 have been defined in the surface 140 of template layer 130 by one of the processes described above with reference to FIGS. 6A, 6B, 7A and 7B, or by another suitable process, surface 140 can be characterized by AFM imaging in contact mode. The resulting topographic image (not shown) is unchanged relative to the topographic image (not shown) taken as described above before charged regions 150, 152 were defined. On the other hand, the resulting friction image (not shown) will clearly show charged regions 150, 152. When the voltage applied is high, e.g., more negative than −8V, and humidity is high, e.g., greater than 80%, the applied voltage can oxidize not only the terminal group of the octadecyltrimethoxyl-silane self assembled monolayer constituting template layer 130 but also the silicon interface below template layer 130. This can be seen in the above-described topographic image and friction image. In the topographic image, charged regions 150, 152 are higher than surrounding uncharged region 154. Charged regions 150, 152 are negatively charged in both situations, since the —COOH groups and SiO₂ have same charge at neutral pH.

FIGS. 8A and 8B shows solid support 110 and the surface 140 of template layer 130 after charged regions 150, 152 have been defined in surface 140 by, for example, either of the definition processes described above with reference to FIGS. 6A/6B and 7A/7B. Charged regions 150, 152 are surrounded by electrically-neutral region 154 that accounts for the remainder of surface 140. FIG. 8C is an enlarged view showing part of template layer 130 and part of charged region 152 defined in the surface 140 of the template layer. In FIG. 8C and the enlarged views described below, the thickness of charged region 152 is exaggerated to enable the charged region to be seen. As noted above, the charged regions are localized at the surface 140 of template layer 130.

Charged regions 150, 152 are arranged in tandem in surface 140: charged region 150 is offset from charged region 152 in the y-direction by a distance that depends on the length of nanostructure 160 (FIG. 1A), The distance d between adjacent ends of the charged regions is typically less than the minimum length of the nanostructures with which the wafer will later be contacted. In the example shown, charged regions 150, 152 are rectangular in shape, and are elongate in the y-direction. Charged regions 150, 152 have a width and a length in the x-direction and y-direction respectively. In one example, the charged regions 150, 152 typically have a width (x-direction dimension) of about 5-20 nm. At this width, the chance of one nanostructure, but no more than one nanostructure attaching to the charged regions, is acceptably high. The length of each charged region 150, 152 is typically less than or equal to the length of the nanostructure. Charged regions 150, 152 may have shapes other than those exemplified, including symmetrical shapes. Charged regions 150, 152 have a negative polarity.

The wafer is contacted with a suspension of positively-charged or electrically-neutral nanostructures. In an example, the wafer is immersed for 20 minutes in a dilute suspension of nanostructures. The suspension is a suspension of carbon nanotubes in 1,2-dichlorobenzene and has a concentration of about 1 μg/ml. The carbon nanotubes are dispersed in the 1,2-dichlorobenzene by ultrasonication and purified by centrifuge. In another example, a drop of the above-described carbon nanotube suspension is rolled across the surface of the template layer several times. The wafer is then washed with 1,2-dichlorobenze and toluene, and is blown dried with dry nitrogen.

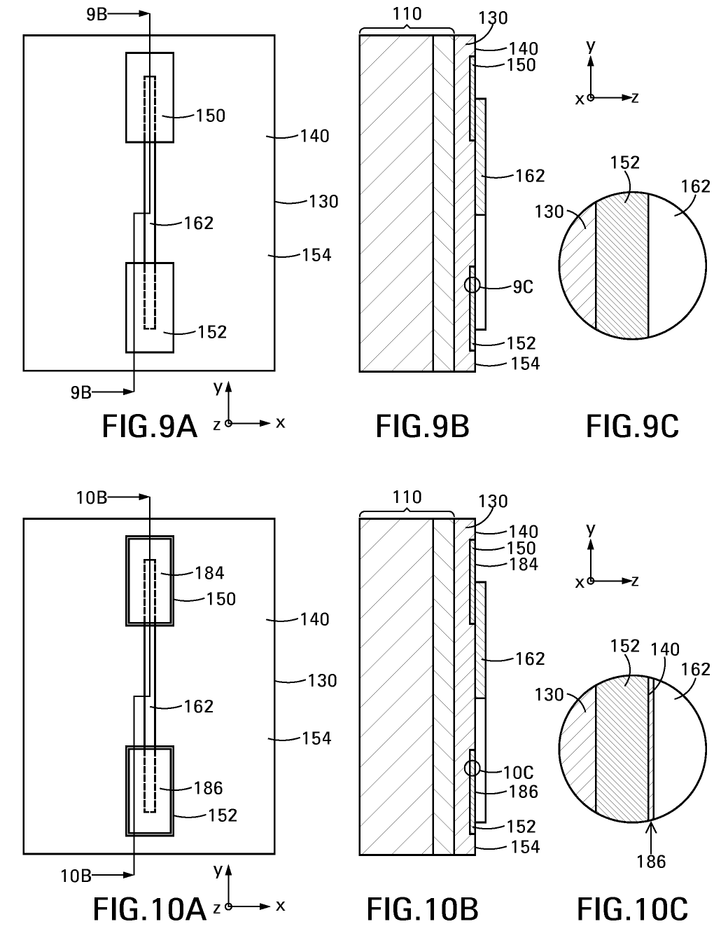

FIGS. 9A and 9B show the surface 140 of template layer 130 with carbon nanotube 162 immobilized thereon by charged regions 150 and 152. Carbon nanotube 162 is an example of nanostructure 160 (FIG. 1A). FIG. 9C is an enlarged view showing part of template layer 130 in which part of charged region 152 is defined, and part of carbon nanotube 162 adjacent the part of charged region 152 shown. Successful immobilization of carbon nanotube 162 on the surface 140 of template layer 130 by charged regions 150, 152 can be confirmed by characterizing surface 140 by AFM imaging in noncontact mode. This approach successfully immobilizes a single carbon nanotube in a bridging relationship to charged regions 150, 152 to the strong affinity between carbon nanotube 162 and —COOH groups in the charged regions.

The processing described above has provided an elongate, electrically-conducting nanostructure 160, i.e., carbon nanotube 162, extending between a pair of spaced, electrically-charged regions 150, 152 arranged in tandem on the electrically-neutral surface 154 of template layer 130 supported by solid support 110.

The wafer is next contacted with a solution of a metal salt. Such contacting causes the positively-charged metal ions to deposit within the charged regions of the template layer. The charged regions are negatively charged. Since the nanostructure is electrostatically bound to the charged regions, the metal ions are deposited proximate to the nanostructure at locations separated along the length of the nanostructure. In an example, the wafer is dipped into a solution of a metal salt for a time and is then removed. Examples of suitable solutions include 100 mM aqueous solutions of silver nitrate AgNO₃, palladium nitrate P_{d}(NO₃)₂ or palladium chloride PdCl₂. Other water-soluble salts of process-compatible metals are known and may be used. Solvents other than water may be used. In an embodiment, the wafer is dipped into an aqueous solution of silver nitrate for five minutes, and is then removed.

FIGS. 10A and 10B show the surface 140 of template layer 130 with carbon nanotube 162 immobilized thereon by charged regions 150 and 152, and additionally regions 184, 186 of metal ions located on the surface of the template layer within charged regions 150, 152, respectively. Each of the regions 184, 186 of metal ions is composed of ions of a metal such as silver, gold or palladium. FIG. 10C is an enlarged view showing part of template layer 130 in which part of charged region 152 is defined, part of carbon nanotube 162 adjacent the part of charged region 152 shown, and part of region 186 of metal ions located on the surface 140 of the template layer.

The wafer is next contacted with a reducing agent. The reducing agent reduces the metal ions within each of the charged regions to form a respective seed region composed of particles of the metal. Since the nanostructure is electrostatically immobilized on the surface of the template layer by the charged regions, the seed regions within the charged regions in the surface of the contact layer are located proximate to the nanostructure at locations separated along the length of the nanostructure. In an example, the wafer is dipped into a 5 mM aqueous solution of sodium borohydride NaBH₄ for about two minutes. Contact with the sodium borohydride reduces the metal ions located in each of the charged regions in the surface of the template layer to particles of the metal that constitute respective seed regions. Other process-compatible reducing agents are known in the art and may be used. Examples of such alternative reducing agents include formaldehyde H₂CO and glutaldehyde OCH(CH₂)₃CHO.

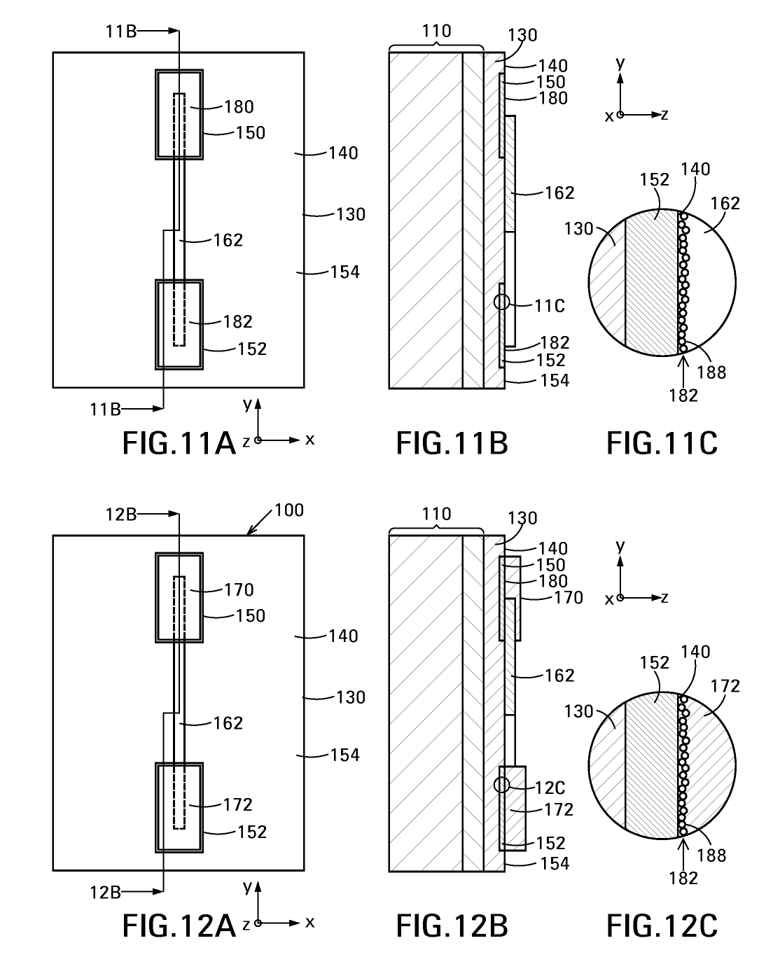

FIGS. 11A and 11B show the surface 140 of template layer 130 with carbon nanotube 162 immobilized thereon by charged regions 150 and 152, and seed regions 180, 182 composed of metal particles, e.g., particles of silver, gold or palladium, on the surface of the template layer within charged regions 150, 152, respectively. FIG. 11C is an enlarged view showing part of template layer 130 in which part of charged region 152 is defined, part of carbon nanotube 162 adjacent the part of charged region 152 shown, and part of seed region 182 located on the surface 140 of template layer 130 in charged region 152. An exemplary one of the metal particles that constitute seed region 182 is shown at 188. The metal particles constituting seed regions 180, 182 result from reducing the metal ions in regions 184, 186 shown in FIGS. 10A-10C.

Metal is selectively deposited over the seed regions to form respective electrodes that complete the fabrication of respective electrodes that electrically contact the nanostructure at respective locations offset from one another along the length of the nanostructure. The metal selectively deposited over the seed regions provides the electrodes with a high electrical conductivity and enables each of the electrodes to make a low-resistance contact with the nanostructure. In one example, the metal is selectively deposited by electroless plating. In another example in which an electrical connection can be conveniently made to the seed regions, the metal is deposited at least in part by conventional electroplating.

FIGS. 12A and 12B show the surface 140 of template layer 130 with carbon nanotube 162 immobilized thereon by charged regions 150 and 152, and electrodes 170, 172 located in charged regions 150, 152, respectively. Electrodes 170, 172 are composed of metal selectively deposited on seed regions 180, 182, respectively, located on the surface 140 of template layer 130 within charged regions 150, 152, respectively. Electrodes 170, 172 each have a location and lateral extent defined by those of the respective one of seed regions 180, 182. FIG. 12C is an enlarged view showing part of template layer 130 in which part of charged region 152 is defined, part of carbon nanotube 162 adjacent the part of charged region 152 shown, and part of electrode 172 whose location and lateral extent are defined by seed region 182. An exemplary one of the metal particles that constitute seed region 182 is shown at 188.

In an example, the wafer is immersed in an electroless plating bath comprising ions of the metal to be deposited to form electrodes 170, 172 and is left in the plating bath until electrodes 170, 172 reach their design thickness. An exemplary electroless plating solution suitable for electrolessly plating gold comprises potassium dicyanoaurate KAu(CN)₂, potassium cyanide KCN, potassium hydroxide KOH and potassium borohydride KBH₄ and operates at 70° C. Other metals that may be deposited by electroless plating to form electrodes 170, 172 include, but are not limited to, copper Cu, nickel Ni and silver Ag. Plating bath formulations and operating conditions suitable for depositing such metals are known in the art and may be used.

As noted above, in embodiments in which electrical connections can be made to seed regions 180, 182, electrodes 170, 172 can be formed by first depositing of a thin layer of metal on seed regions 180, 182 using electroless plating, and then depositing a thicker layer of metal by electroplating. The metal deposited by electroplating may be the same as or different from that deposited by electroless plating. The metal deposited by electroplating may be composed of layers of different metals.

Once electrodes 170, 172 have reached their design thicknesses, the wafer is removed from the plating bath, washed and dried. A conventional wafer dividing process is then used to divide the wafer into individual electronic devices such as electronic device 100 described above with reference to FIGS. 1A-1C. Optionally, the wafer is subject to additional processing, such as processing to form electrical connections to electrodes 170, 172, before the wafer is divided into individual electronic devices. The electronic devices can also be tested and/or characterized before the wafer is divided.

In the examples described above, nanostructure 160 is shown as a single elongate nanoelement, i.e., single carbon nanotube 162. However, in many applications, it is advantageous for nanostructure 160 to be composed of two or more nanoelements arranged side-by-side and extending between charged regions 150, 152. An embodiment of nanostructure 160 composed of two or more nanoelements increases the current-carrying capability of the electronic device compared with an embodiment of nanostructure 160 composed of a single nanoelement. FIGS. 13A and 13B are respectively a plan view and a cross-sectional view showing an example of a nanostructure-based electronic device 300 in accordance with another embodiment of the invention. Electronic device 300 is structurally similar to above-described electronic device 100, but the width (x-direction dimension) of charged regions 350, 352 in increased relative to that of charged regions 150, 152 (FIG. 1A) so that charged regions 350, 352 can accommodate two or more nanoelements arranged side-by-side. This allows as many nanoelements as can be accommodated by the width of charged regions 350, 352 to extend between the charged regions. In the simplified example shown, nanostructure 160 is composed of three carbon nanotubes 364, 365 and 366 arranged side-by-side. In the example shown, electrodes 370, 372 are co-extensive with charged regions 350, 352, respectively, and electrically contact nanostructure 160, i.e., carbon nanotubes 364-366, at locations offset from one another along the length of the nanostructure.

In a more typical example, the width of charged regions 350, 352 was 100 nm. Charged regions 350, 352 of this width are capable of immobilizing as many as fifty 2 nm-diameter carbon nanotubes on the surface 140 of template layer 130. This embodiment of nanostructure 160 would provide electronic device 300 with a current-carrying capacity of approximately fifty times that of electronic device 100 (FIG. 1A).

In embodiments such as that just described in which nanostructure 160 is composed of two or more nanoelements, the position of each nanoelement can be individually defined by shaping the charged regions to include sub-regions. Opposed pairs of the sub-regions immobilize a single nanoelement on the surface of the template layer. In one example, each of the charged regions is comb-shaped. Each comb-shaped charged region comprises two or more teeth arrayed in the x-direction. Each of the teeth of one charged region is located opposite a corresponding tooth of the other charged region. The opposed teeth are offset from one another in the y-direction and have a width in the x-direction sufficient to accommodate one nanoelement, but not two nanoelements. Each nanoelement is immobilized on the surface of the template layer extending between a tooth of one charged region and the opposed tooth of the other charged region. The electrodes whose shapes are defined by the charged regions may also be comb shaped.

FIG. 14 is a plan view showing an example of a nanostructure based electronic device in which charged regions 450, 452 are comb-shaped. In the example shown, charged region 450 comprises three teeth, an exemplary one of which is shown at 454, extending towards charged region 452. Charged region 452 comprises three teeth, an exemplary one of which is shown at 456, extending towards charged region 450. The width of each tooth is sufficient to accommodate one nanoelement, e.g., nanoelement 366, but not two nanoelements. The number of teeth constituting the charged regions defines the number of nanoelements constituting nanostructure 160.

Charged regions that are comb-shaped, as shown, or have another complex shape, can easily be defined using the charged regions definition processes described above with reference to FIGS. 6A, 6B, 7A and 7B. In practical electronic devices, the number of teeth and, hence, nanoelements is greater then the number illustrated. More typically, the number of teeth in each charged region is about 50.

In the example shown, electrode 470 is co-extensive with charged region 450 and includes teeth, an exemplary one of which is shown at 474. Moreover, electrode 472 is co-extensive with charged region 452 and includes teeth, an exemplary one of which is shown at 476. In embodiments in which the spacing between the teeth is small and the electrodes 470, 472 are thick, the teeth may merge to form a substantially rectangular electrode.

The current-carrying capacity of the electronic device could be further increased by using an embodiment of nanostructure 160 in which one or more additional layers of nanoelements are stacked on top of the layer of nanoelements described above with reference to FIGS. 13A and 13B. FIGS. 15A and 15B are respectively a plan view and a cross-sectional view showing an example of a nanostructure-based electronic device 500 in accordance with another embodiment of the invention. In this embodiment, nanostructure 160 is composed of a first layer 561 of nanoelements immobilized on the surface 140 of template layer 130 by charged regions 550, 552, and a second layer 563 of nanoelements immobilized on first layer 561 of nanoelements, also by charged regions 550, 552. In this simplified example, the first layer 561 of nanoelements is composed of carbon nanotubes 564, 565 and 566, and the second layer 563 of nanoelements is composed of carbon nanotubes 567 and 568. In more typical examples, the number of nanoelements in each layer is substantially greater than in the example shown. In one example, first layer 561 is composed of fifty carbon nanotubes arranged side-by-side. Moreover, the number of layers of nanoelements constituting nanostructure 160 may be greater than the two illustrated. The different layers may be composed of differently-shaped nanoelements whose shapes are chosen so that each layer will stack on the previous layer in an orderly manner. For example, any nanostructure with a circular cross-section will stack in an orderly manner. The stacked layers can also composed of different nanoelements that stack in an orderly manner.

Electronic device 500 is fabricated using a process similar to that described above with reference to FIGS. 3A-12C. Performing the deposition process described above with reference to FIGS. 9A-9C the first time immobilizes the nanoelements constituting first layer 561 in contact with surface 140. Performing the deposition process described above with reference to FIGS. 9A-9C a second time immobilizes the carbon nanotubes constituting second layer 563 on the first layer 561 of nanoelements. To prevent the first layer 561 of nanoelements from screening the charge in charged regions 550, 552 from nanoelements to be subsequently deposited as the second layer 563, the nanoelements deposited to form first layer 561 are shorter than those deposited to form second layer 563. When more than two layers of nanoelements are to be deposited, the nanoelements deposited in each iteration of the deposition process are progressively longer than those deposited in the previous iteration. Charged regions 550, 552 are dimensioned such that the distance D between their remote ends is greater than the longest of the nanoelements. In the example shown, electrodes 570, 572 are co-extensive with charged regions 550, 552, respectively, and electrically contact nanostructure 160, i.e., carbon nanotubes 564-568, at locations offset from one another along the length of the nanostructure.

Another way to increase the current-carrying capacity of the electronic device 300 is to embody nanostructure 160 as a single nanorope, or as two or more nanoropes arranged side-by-side. Each nanorope is composed of two or more helical nanotubes that are intertwined. Nanoropes are described, for example, by Su et al. in Self-Organization of Triple-Stranded Carbon Nanoropes, 5 PHYSCHEMCOMM 34-36 (2002), incorporated by reference.

In the examples described above, nanostructure-based electronic devices 100, 300, 400 and 500 are each composed of solid support 110 having a single, elongate, electrically-conducting nanostructure 160 immobilized by a pair of charged regions in the surface 140 of template layer 130 located on the surface 120 of solid support 110. Electrodes located in the charged regions electrically contact the nanostructure at locations offset from one another along the length of the nanostructure. In other examples (not shown), the nanostructure-based electronic device is composed of a solid support having more than one elongate, electrically-conducting nanostructure immobilized on the surface of a template layer located on the surface of the solid support. Each nanostructure is immobilized by a respective pair of charged regions in the surface of the template layer. Respective electrodes located in the charged regions electrically contact the nanostructure at locations offset from one another along the length of the nanostructure. Optionally, additional conductors (not shown) located on the surface of the template layer electrically connect one or more of the electrodes to another of the electrodes and/or to other electronic circuit elements located on surface 140.

In the examples described above, each electrode is substantially co-extensive with the underlying charged region. This allows the electrodes to be fabricated as described above without the need for a photolithographic process to define their position. However, for some applications, the electrical resistance of the electrodes that are fabricated by depositing metal in the charged regions can be quite high. To reduce the electrical resistance of, for example, electrodes 170, 172 described above with reference to FIGS. 1A-1C, electrodes 170, 172 may comprise an additional layer of metal substantially greater in thickness than the thickness of electrodes 170, 172 fabricated as described above with reference to FIGS. 12A-12C. Such thickened electrodes overlap the original electrodes and additionally typically extend beyond the charged regions in the x-y plane. Thickened electrodes are fabricated by depositing an additional layer of metal over electronic device 100 after electrodes 170, 172 have been fabricated as described above with reference to FIGS. 12A-12C. A photolithographically-defined etch or lift-off process is performed to remove all of the metal layer except a portion of the metal layer in a region that overlays each electrodes 170, 172, and that extends in the x-y plane beyond charged regions 150, 152, respectively. Electrodes 170, 172 and the portions of the metal layer overlaying them then collectively constitute the thickened electrodes of electronic device 100. In such an embodiment, the electrodes of the electronic device extend in the x-y plane beyond the underlying charged regions. Fabrication of the thickened electrodes involves a photolithographic process in which a mask is aligned with electrodes 170, 172. However, since electrodes 170, 172 are larger than nanostructure 160, the mask alignment is substantially less critical than the mask alignment in a conventional process in which the mask is aligned with nanostructure 160.

This disclosure describes the invention in detail using illustrative embodiments. However, the invention defined by the appended claims is not limited to the precise embodiments described.

We claim:

1. An electronic device, comprising:
a solid support having a solid support surface;
an organic template layer on the solid support surface, the template layer having a surface comprising a pair of spaced, electrically-charged regions arranged in tandem in an electrically-neutral background;
an elongate, electrically-conducting nanostructure extending between the charged regions; and
on the surface of the template layer, electrodes at least co-extensive with the charged regions.

2. The electronic device of claim 1, in which the nanostructure comprises a single carbon nanotube.

3. The electronic device of claim 2, in which the nanostructure additionally comprises one or more additional carbon nanotubes, the single nanotube and the additional nanotubes arranged side-by-side.

4. The electronic device of claim 2, in which the nanostructure additionally comprises one or more additional carbon nanotubes, the single nanotube and the additional nanotubes collectively constituting a nanorope.

5. The electronic device of claim 1, in which the nanostructure comprises one or more doped semiconductor nanowires.

6. The electronic device of claim 1, in which the nanostructure comprises one or more undoped semiconductor nanowires.

7. The electronic device of claim 1, in which the nanostructure comprises one or more metal nanowires.

8. The electronic device of claim 1, in which the nanostructure comprises one or more doped semiconductor nanoribbons.

9. The electronic device of claim 1, in which the nanostructure comprises one or more doped semiconductor nanofibers.

10. The electronic device of claim 1, in which:
the electronic device additionally comprises, in each of the charged regions and co-extensive therewith, a respective seed region comprising metal particles; and
the electrodes each overlay a respective one of the seed regions.

11. The electronic device of claim 10, in which the seed regions are of a metal different from the electrodes.

12. The electronic device of claim 1, in which:
one of the charged regions is offset from the other of the charged regions in a first direction; and
the charged regions are elongate in the first direction.

13. A method of making an electronic device, the method comprising:
providing an elongate, electrically-conducting nanostructure immobilized by a pair of spaced, electrically-charged regions arranged in tandem on an electrically-neutral surface of a template layer supported by a solid support;
contacting the template layer with a solution of a metal salt to deposit metal ions within the electrically-charged regions;
reducing the metal ions within each of the charged regions to form a respective seed region comprising particles of the metal; and
selectively depositing metal over the seed region to form electrodes that electrically contact the nanostructure at respective locations offset from one another along the length of the nanostructure.

14. The method of claim 13, in which the providing comprises:
providing a substrate, the substrate having a substrate surface;
forming the template layer on the substrate surface; and
selectively subjecting regions of the surface of the template layer at desired locations to an electric field that electrochemically causes the regions of the template layer to be locally charged.

15. The method of claim 14, in which the subjecting comprises:
providing an electrically-conducting scanning probe microscope probe comprising a probe tip;
locating the probe tip adjacent the surface of the template layer in the desired location of one of the charged regions; and
applying a voltage between the probe tip and the substrate.

16. The method of claim 15, in which:
the charged regions of the template layer are elongate in a first direction; and
the subjecting additionally comprises moving one of the probe tip and the substrate relative to the other in the first direction.

17. The method of claim 14, in which the subjecting comprises:
providing an electrode tool comprising electrodes each having a shape corresponding to a desired shape of a respective one the charged regions;
locating the electrodes of the electrode tool adjacent the surface of the template layer in a desired location of the charged regions; and
applying a voltage between the electrodes of the electrode tool and the substrate.

18. The method of claim 14, in which the providing additionally comprises:
contacting the surface of the template layer with a suspension comprising elongate nanostructures; and
removing from the surface of the template layer ones of the nanostructures not immobilized thereon by contact with the charged regions.

19. The method of claim 14, in which the providing additionally comprises:
contacting the surface of the template layer with a charge-reversing agent; and
contacting the surface of the template layer with a suspension comprising elongate nanostructures, the nanostructures having the same electrical charge polarity as the charged regions.

20. The method of claim 13, in which the reducing comprises contacting the template layer with a reducing agent to form the metal particles of the seed regions from the ions of the metal.

21. The method of claim 13, in which the depositing comprises an electroplating process.

22. The method of claim 13, in which the depositing comprises an electroless plating process.
